(19) United States
(12) Patent Application Publication
(10) Pub. No.: US 2025/0233031 A1
(43) Pub. Date: Jul. 17, 2025

(54) SUBSTRATE FOR ELECTRONIC DEVICE

(71) Applicant: Soitec, BERNIN (FR)

(72) Inventors: Hugo Biard, BERNIN (FR); Damien Radisson, BERNIN (FR); Eric Guiot, BERNIN (FR)

(21) Appl. No.: 18/854,045

(22) PCT Filed: Apr. 4, 2023
(86) PCT No.: PCT/FR2023/050479

§ 371 Date: Oct. 3, 2024

(30) Foreign Application Priority Data
Apr. 4, 2022 (FR) FR2203050

(51) Int. Cl. H01L 23/14; H01L 21/02; H01L 21/04; H01L 23/00; H01L 23/13; H01L 23/373; H01L 23/66; H01L 25/065

(52) U.S. Cl. CPC H01L 23/147; H01L 21/02378; H01L 21/02428; H01L 21/02529; H01L 21/02598; H01L 21/0475; H01L 23/13; H01L 23/3735; H01L 23/66; H01L 24/32; H01L 25/0655; H01L 2224/32227; H01L 2224/32238; H01L 2924/35121

(57) ABSTRACT

A substrate for a power or radiofrequency electronic device includes a self-supporting support substrate made of polycrystalline silicon carbide and a surface layer of monocrystalline silicon carbide that extends over a front face of the support substrate. The support substrate has at least one porous portion extending from a rear face of the support substrate. The porous portion has a degree of porosity of greater than 5%.

### CROSS-REFERENCE TO RELATED APPLICATIONS

This application is a national phase entry under 35 U.S.C. § 371 of International Patent Application PCT/FR2023/050479, filed Apr. 4, 2023, designating the United States of America and published as International Patent Publication WO 2023/194682 A1 on Oct. 12, 2023, which claims the benefit under Article 8 of the Patent Cooperation Treaty of French Patent Application Serial No. FR2203050, filed Apr. 4, 2022.

### TECHNICAL FIELD

The present disclosure relates to a substrate for an electronic device, in particular, for application to radiofrequency or power electronics. The present disclosure also relates to an electronic device comprising such a substrate, and to a process for manufacturing such a substrate.

### BACKGROUND

Silicon carbide (SiC) is widely used for the manufacture of radiofrequency or power electronic components.

A substrate for producing such components typically comprises a support substrate, which may be made of polycrystalline SiC (p-SiC), and a surface layer of monocrystalline SiC (m-SiC) extending on the support substrate. Electronic components are manufactured in or on the layer of monocrystalline SiC. The structure is cut in the form of chips each comprising one or more electronic components. Each chip is brazed to a direct bonded copper stack comprising metal layers, a thermally conductive ceramic and a heat sink.

The heat is thus discharged mainly via the direct bonded copper stack, involving significant thermal stresses on the filler that links the electronic component and the upper metal layer of the direct bonded copper stack by brazing.

However, the coefficient of thermal expansion (CTE) and the Young's modulus of the SiC and of the direct bonded copper stack, in particular, the copper, are very different. Variations in temperature therefore cause uneven deformations in the various layers below and above the braze.

As a result, the filler is subject to high loads, thereby causing cracks, delaminations or flaking at the interface of the braze, resulting in a shortened service life of the device.

To reduce these mechanical stresses, it is known practice to thin the layers of the composite structure, in particular, of the base substrate made of polycrystalline SiC. However, it takes a lot of time and effort to abrade such a base substrate, resulting in an elevated cost of the electronic component. Moreover, the thinning involves a risk of breakage, making the composite structure unusable.

Another solution is to modify the materials used to produce the braze, this being difficult to implement, in particular, while maintaining the mechanical stability and the electrical and thermal conductivity of the braze.

### BRIEF SUMMARY

An aim of the present disclosure is to propose a composite structure for producing electronic devices, having a better resistance to the temperature cycles while avoiding cracks, delaminations and flaking at the braze interface.

To this end, the present disclosure proposes a substrate for a radiofrequency or power electronic device, comprising:
a support substrate made of polycrystalline silicon carbide having a front face and a rear face, the support substrate being self-supporting, and
a surface layer of monocrystalline silicon carbide extending on the front face of the support substrate,
wherein the support substrate has at least one porous portion extending from the rear face, the porous portion having a porosity greater than 5%.

The support substrate has a thickness greater than 50 μm, advantageously greater than 80 μm, more advantageously greater than 100 μm and more advantageously still greater than 150 μm.

The porous portion preferably comprises a layer of porosified SiC.

In some embodiments, the support substrate comprises a non-porous portion between the surface layer of monocrystalline SiC and the porous portion.

In some embodiments, the porous portion has a rear part having a first porosity and a front part having a second porosity lower than the first porosity.

The porous portion may have a porosity gradient that decreases from the rear face to the front face.

The porous portion may have pores filled with a material having a Young's modulus lower than the Young's modulus of the silicon carbide.

Advantageously, the mean distance between the pores is greater than 10 nm, preferably greater than 50 nm.

The present disclosure also relates to an electronic device comprising a substrate as described above and at least one radiofrequency or power electronic component formed in or on the surface layer of monocrystalline silicon carbide.

The electronic device preferably additionally comprises a heat discharge device, the substrate being brazed to the heat discharge device via a filler such that the filler is in integral contact with at least part of the porous portion on the rear face of the support substrate.

Another subject of the present disclosure concerns a process for manufacturing a radiofrequency or power electronic device comprising:
a self-supporting support substrate made of polycrystalline silicon carbide having a front face and a rear face, and
a surface layer of monocrystalline silicon carbide extending on the front face of the support substrate,
wherein the process comprises a step of forming, in the support substrate, at least one porous portion extending from the rear face, the porous portion having a porosity of greater than 5% and a thickness greater than 100 nm, advantageously greater than 1 μm, and more advantageously greater than 3 μm.

The process may additionally comprise a step of assembling the surface layer and the support substrate.

The support substrate preferably has a thickness greater than 50 μm, advantageously greater than 80 μm, more advantageously greater than 100 μm and more advantageously still greater than 150 μm.

Advantageously, the formation of the support substrate comprises a step of porosifying at least part of a base substrate of non-porous silicon carbide to form the porous portion.

In some embodiments, the porosification is carried out on all of the base substrate to form a completely porous support substrate.

The porosification may be carried out so as to form a porosity gradient that decreases in the porous portion from the rear face to the front face.

The porosification may be carried out so as to form a bonding zone having a porosity of less than 40% on the front face of the support substrate.

In some embodiments, the process comprises a step of filling at least some of the pores of the porous portion with a material having a Young's modulus lower than the Young's modulus of the silicon carbide.

The process may additionally comprise a step of thinning the support substrate via the rear face, such that the thickness of the porous portion remains greater than or equal to 100 nm.

### BRIEF DESCRIPTION OF THE DRAWINGS

Other features and advantages of the present disclosure will emerge from the following detailed description, with reference to the appended drawings, in which:

FIG. 1 illustrates a device comprising two electronic components produced from a substrate according to the present disclosure and a direct bonded copper stack.

FIG. 2 illustrates a substrate according to the present disclosure comprising a surface layer made of monocrystalline silicon carbide and a support substrate comprising a porous portion.

FIG. 3 illustrates a substrate according to the present disclosure comprising a surface layer made of monocrystalline silicon carbide and a support substrate comprising a porous portion made of porosified polycrystalline SiC and a non-porous portion.

FIG. 4 illustrates a substrate according to one embodiment comprising a surface layer made of monocrystalline silicon carbide and a support substrate comprising a porous portion made of sintered SiC and a non-porous portion.

FIG. 5 illustrates a substrate according to another embodiment comprising a surface layer made of monocrystalline silicon carbide and a support substrate comprising a non-porous portion and a porous portion comprising two zones of different porosities.

FIG. 6 is a graph for measuring the resistance to fracture of a substrate made of porous silicon carbide as a function of the porosity of the substrate.

FIGS. 7A to 7D illustrate the steps of one embodiment of a process for manufacturing a substrate according to the present disclosure.

FIGS. 8A to 8C illustrate the steps of another embodiment of a process for manufacturing a substrate according to the present disclosure.

FIGS. 8D to 8I illustrate the steps of a variant of the embodiment of the process illustrated in FIGS. 8A to 8C.

FIGS. 9A and 9B illustrate the steps of a third embodiment of a process for manufacturing a substrate according to the present disclosure.

FIGS. 10A to 10F illustrate the steps of a fourth embodiment of a process for manufacturing a substrate according to the present disclosure.

FIGS. 11A to 11E illustrate the steps of a fifth embodiment of a process for manufacturing a substrate according to the present disclosure.

FIG. 12 is a graph of the Young's modulus of various samples made of porous silicon carbide as a function of the porosity of the samples.

FIG. 13 is a graph of the Young's modulus of various samples made of silicon carbide.

To make the figures easier to read, the structures illustrated have not necessarily been shown to scale.

### DETAILED DESCRIPTION

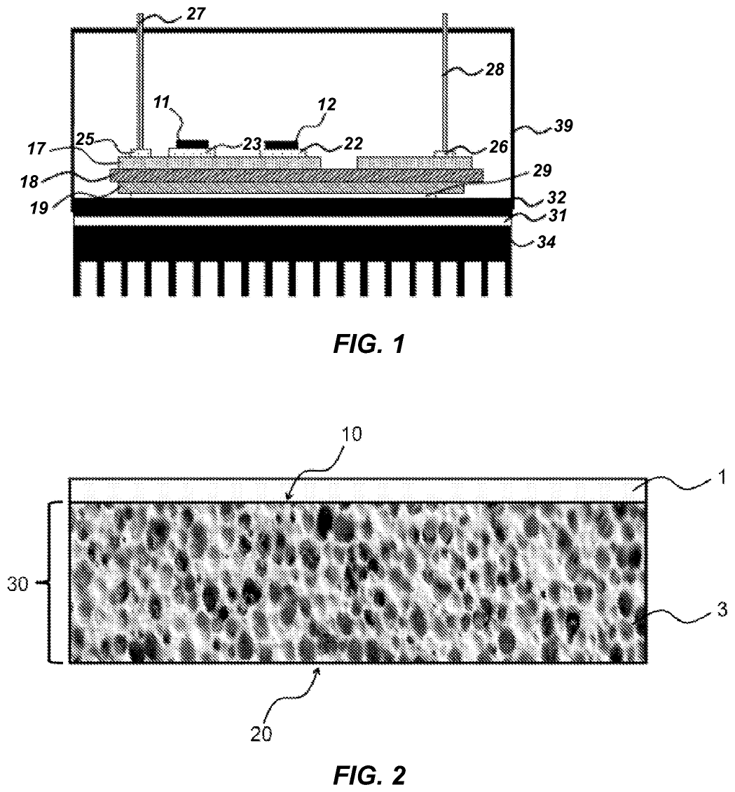

FIG. 1 illustrates a radiofrequency or power electronic device comprising one or more electronic chips 11, 12 produced from a substrate according to the present disclosure. The chips may be linked by interconnections. In the case of a radiofrequency device, the electronic chip may bear a lateral device made of gallium nitride.

The electronic chips 11, 12 are mounted on a direct bonded copper structure via brazes 22, 23. This direct bonded copper (DBC) structure comprises two copper metallizations 17, 19 and a substrate 18 made of a thermally conductive and electrically insulating ceramic, for example, made of aluminum nitride. Electrical connections 27, 28 are fixed to the copper metallization 17 via brazes 25, 26.

A braze 29 fixes the device to a heat sink 34 and a base plate 32. A layer of thermal grease 31 ensures thermal contact between the heat sink 34 and the base plate 32. The radiofrequency or power electronic device is encapsulated in a casing 39, which is typically made of plastic.

Each chip is formed from a substrate comprising a support substrate made of silicon carbide and a surface layer of monocrystalline silicon carbide in or on which is formed at least one power electronic component or radiofrequency electronic component.

The surface layer made of monocrystalline silicon carbide typically has a thickness ranging between 100 nm and 1500 nm. On this surface layer, it is possible to epitaxially deposit a monocrystalline layer made of silicon carbide with a thickness ranging between 1 μm and 150 μm, in which at least part of the electronic component is formed.

The support substrate has a front face, on which the surface layer extends, and a rear face opposite to the front face.

The surface layer may have been assembled on the support substrate, which may then be polycrystalline, according to embodiments that will be described later on.

The support substrate may be itself in one piece or be made up of a stack of at least two layers. The thickness of the support substrate is preferably chosen such that the support substrate is self-supporting without the surface layer, which is to say that it is mechanically stable enough to be manipulated on its own, without adding an additional handling substrate or support. To this end, the support substrate typically has a thickness greater than 150 μm, advantageously greater than 100 μm, more advantageously greater than 80 μm and more advantageously still greater than 50 μm. The use of a self-supporting support substrate advantageously makes the steps of manufacturing the substrate easier.

In some cases, the electronic device may be manufactured from a support substrate without a limit on its thickness, which is not necessarily self-supporting. In this case, the heat discharge device makes it possible to mechanically stabilize the electronic component. The manufacture of such a substrate may require a handling support. However, the support substrate may be produced according to the same embodiments as a self-supporting support substrate.

In the case of a power electronic device, good electrical conductivity between the thin layer and the support substrate is necessary. For such a device, the support substrate has, for example, an electrical resistivity of 50 mΩ·cm or less, in particular, 20 mΩ·cm or less.

In the case of a radiofrequency device, the support substrate advantageously has a high electrical resistivity, for example, an electrical resistivity greater than 500 Ωcm.

The support substrate has at least one porous portion that extends from the rear face. By contrast, the surface layer is non-porous, which is to say that it has a porosity of less than 5% or zero.

The porosity of the silicon carbide is defined as the unoccupied volume fraction within the silicon carbide, the volume being able to be filled with air or another gas or solid inclusions of another material. For example, pores of a layer of porous silicon carbide may be filled with carbon inclusions.

The pores may be interconnected or separate from one another, depending, in particular, on the method for forming the porous layer. Typically, pores resulting from electrochemical porosification of the silicon carbide are at least partially interconnected and are generally filled with air. In the case of the porous silicon carbide obtained by sintering, the pores are typically separate from one another, and may be at least partially filled with carbon inclusions.

In the case of air-filled and interconnected pores, the porosity can be measured by gravimetry. In other cases, the porosity can be measured by reflectivity of a porous surface of the silicon carbide. It is also possible to measure the porosity by observing a cross section of the porous silicon carbide using an optical microscope or an electron beam scan and by estimating the quotient between the surface area taken up by pores and/or inclusions and the surface area taken up by the silicon carbide.

The porosity of the porous portion of the support substrate advantageously ranges between 5% and 30% and, in the case of a substrate made of porosified silicon carbide, more advantageously between 5% and 20%. The porosity may be constant over the entire thickness of the porous portion or be variable gradually or continuously along a gradient, according to embodiments described later on.

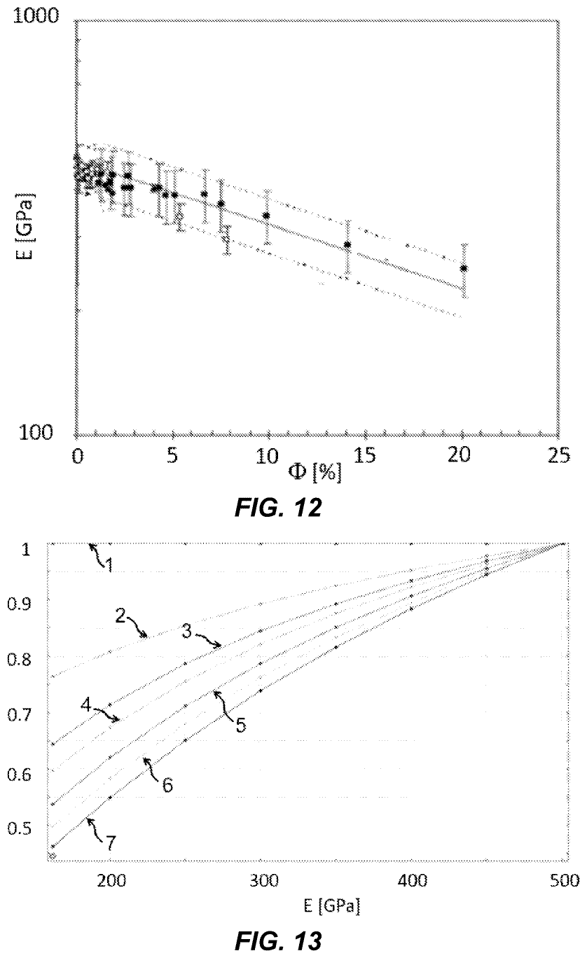

The presence of such a porosity makes it possible to reduce the Young's modulus of the silicon carbide. FIG. 12 illustrates the Young's modulus (modulus of elasticity, E) of the silicon carbide as a function of the porosity Φ according to L.L. Snead et al. In spite of the broad dispersion, it is noted that the reduction in the Young's modulus is visible even for low porosities and is particularly marked from a porosity of approximately 5%.

If the pores are filled with inclusions of a solid material, the solid material advantageously has a Young's modulus less than that of the silicon carbide, in order to not offset the reduction in the Young's modulus afforded by the porosity of the silicon carbide. Furthermore, to not adversely affect the electrical conductivity of the support substrate, the solid material is advantageously an electrical conductor. For example, the inclusions may comprise carbon, silicon, a metal or a metal alloy.

A porosity less than or equal to 30% makes it possible to conserve an acceptable strength at break in the face of the mechanical stresses likely to be applied to the chip, in particular, when all of the support substrate is porous. FIG. 6 shows measurements of the strength at break in MPa·m^{1/2} as a function of the porosity of a sample of porous silicon carbide. For a porosity up to approximately 25%, the modification of the strength at break is negligible for the behavior of the electronic chip.

In some embodiments, the porous portion extends over the entire thickness of the support substrate.

In other embodiments, the porous portion extends only over part of the thickness of the support substrate. In this case, a non-porous intermediate portion extends between the porous portion and the surface layer. Such a configuration typically has a better resistance to fracture of the substrate.

In all cases, the porous portion has a total thickness greater than 100 nm, preferably greater than 1 μm, or even greater than 3 μm.

By virtue of such a thickness, combined with the aforementioned porosity, the porous portion of the support substrate has a Young's modulus considerably lower than that of the non-porous silicon carbide and thus has a behavior more favorable to the reduction in mechanical stresses exerted on the filler of the braze when the device is subject to variations in temperature.

FIG. 13 is a graph (obtained by a computer simulation) of the relative stress at the point of fatigue in the braze as a function of the Young's modulus E of various substrates made of silicon carbide, having a porous portion of various thicknesses. The total thickness of each substrate is 350 μm. The curve 1 corresponds to a substrate that does not have a porous portion, the curve 2 corresponds to a thickness of the porous portion of 1 μm, the curve 3 to 5 μm, the curve 4 to 10 μm, the curve 5 to 25 μm, the curve 6 to 50 μm, and the curve 7 corresponds to a thickness of the porous portion of 100 μm. Each curve presents the stress in the braze at the outermost point of contact between the braze and the porous SiC, divided by the stress if no porous layer is present.

The stress at the point of fatigue of the braze decreases as the thickness of the porous portion increases. In the simulations, it is assumed that the Young's modulus of the porous SiC depends on the porosity as shown in FIG. 12. For example, in the case of a porosity of 5%, the Young's modulus is 400 GPa. In the case of a layer 10 μm thick (curve 4), a relative stress at the point of fatigue of 0.93 is obtained, which is to say the stress is decreased by 7% compared to a substrate without a porous portion. For a porosity of 15%, corresponding to a Young's modulus of 300 GPa, and a porous layer 20 μm thick, the relative stress at the point of fatigue is 0.8 and therefore decreased by 20% compared to a substrate without a porous portion.

The Young's modulus of the porous portion of the support substrate, which is situated at the braze interface, is closer to the Young's modulus of the DBC structure than the Young's modulus of the surface layer. This implies that the deformations caused by variations in temperature are less significant and are closer to those of the DBC structure and of the braze. Consequently, the mechanical stresses exerted on the braze owing to these deformations are less significant than in the known chips. The reduction of these stresses lengthens the service life of the braze and of the radiofrequency or power electronic device.

Lastly, the presence of such a porous portion on the rear face of the substrate does not adversely affect the electrical conductivity of the substrate in power applications.

### EXEMPLARY EMBODIMENTS

FIG. 2 illustrates a first substrate according to the present disclosure, comprising a support substrate 30 and a surface layer 1. The support substrate 30 is made up of a single porous portion 3 made of porous silicon carbide, having a uniform porosity. This porous portion is made of sintered silicon carbide, porosified polycrystalline silicon carbide or porosified monocrystalline silicon carbide. The porous portion extends from the rear face 20 to the front face 10 of the support substrate 30. The surface layer 1 is made of non-porous monocrystalline silicon carbide. This layer is arranged on the front face of the support substrate 30. In some embodiments, the porous portion and the surface layer are formed in one piece from a single substrate of monocrystalline silicon carbide.

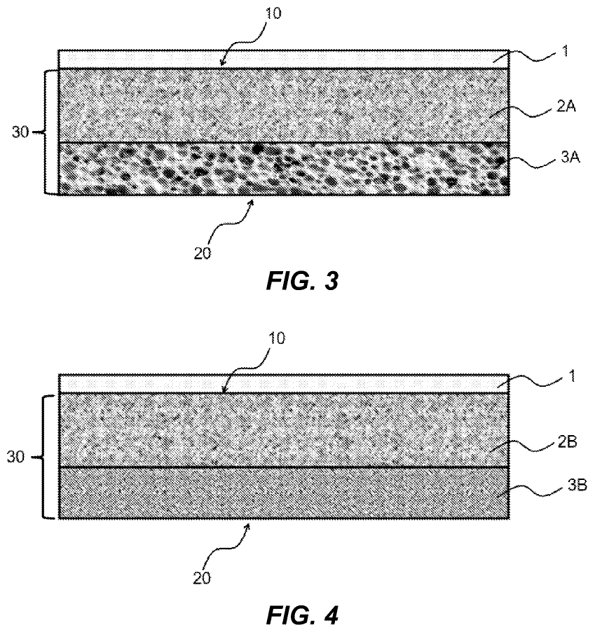

FIG. 3 illustrates a second embodiment in which the support substrate 30 comprises a portion 3A made of porosified silicon carbide extending from the rear face 20 of the substrate. The porosity of this portion 3A is uniform. The pores are interconnected and filled with air. The support substrate 30 additionally comprises a non-porous portion 2A made of polycrystalline silicon carbide arranged between the porous portion and the front face 10 of the support substrate 30. A surface layer 1 made of non-porous monocrystalline silicon carbide is arranged on the front face 10 of the support substrate 30.

FIG. 4 illustrates a third embodiment, in which the support substrate 30 comprises a portion 3B made of sintered silicon carbide extending from the rear face 20 of the substrate. The sintered silicon carbide comprises carbon inclusions that may be separate from one another. The pores are thus filled with carbon, and typically are not interconnected. The porosity of this portion is uniform. The support substrate 30 additionally comprises a non-porous portion 2B made of polycrystalline silicon carbide arranged between the porous portion 3B and the front face 10 of the support substrate 30. A surface layer 1 made of non-porous monocrystalline silicon carbide is arranged on the front face 10 of the support substrate 30.

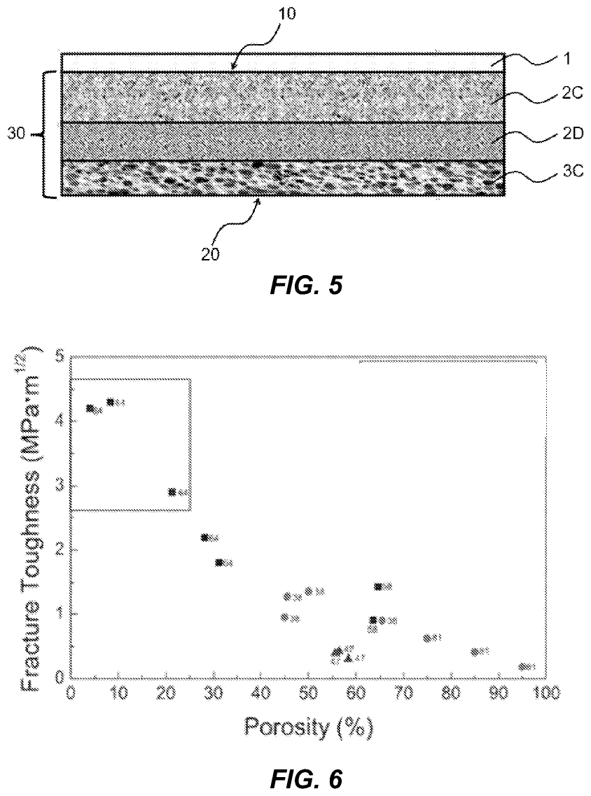

FIG. 5 illustrates a fourth embodiment, in which the support substrate 30 comprises the following in succession, from its rear face 20 to its front face: a first porous portion 3C made of porosified silicon carbide, a second porous portion 2D made of sintered silicon carbide and a non-porous portion 2C. The pores of the first porous portion 3C are interconnected and filled with air. The pores of the second porous portion 2D are filled with carbon inclusions and are separate from one another. The porosity of the layer 3C made of porosified silicon carbide is greater than the porosity of the portion 2D made of sintered silicon carbide. A surface layer 1 made of non-porous monocrystalline silicon carbide is arranged on the front face 10 of the support substrate 30.

In other embodiments that are not illustrated, the porous portion made of porosified silicon carbide has a porosity gradient, such that the porosity decreases from the rear face in the direction toward the front face of the support substrate.

In other embodiments that are not illustrated, multiple portions made of sintered silicon carbide or porosified silicon carbide may be superposed so as to form a support substrate 30 or part of a support substrate 30. The size and the shape of the pores may be similar or different in the various porous portions. Advantageously, the mean distance between the pores is greater than 10 nm, preferably greater than 50 nm, in each porous portion present in the substrate in order to avoid the formation of a possible depletion zone in the SiC.

In some embodiments, a support substrate that may be non-self-supporting is used to form a radiofrequency or power electronic device. The substrate comprises a support substrate made of polycrystalline silicon carbide having a front face and a rear face, and a surface layer of monocrystalline silicon carbide extending on the front face of the support substrate, wherein the support substrate has at least one porous portion extending from the rear face, the porous portion having a porosity greater than 5%. At least one radiofrequency or power electronic component is formed in or on the layer of monocrystalline silicon carbide.

The device may additionally comprise a heat discharge device, the substrate being brazed to the heat discharge device via a filler such that the filler is in integral contact with at least part of the porous portion on the rear face of the support substrate.

### Manufacture of the Substrate

Various embodiments of the steps for manufacturing a substrate will now be described.

The formation of a substrate according to the present disclosure comprises the formation of at least one porous portion.

A porous portion may be formed by porosifying a substrate of silicon carbide. The known methods for porosifying silicon carbide, some of which are described or referenced in the publications by Y. Shishkin et al. and Gautier et al. can be applied to form the porous portion. The porosification can be carried out from the front face or from the rear face of the substrate.

A porosification step may, for example, be carried out by immersion in an acid bath or electrochemically or photoelectrochemically. Electrochemical porosification may be an electrochemical anodization in which the portion to be porosified is placed in an electrolyte such as a solution comprising hydrofluoric acid and/or ethanol. An anode and a cathode that are immersed in the electrolyte are connected to a source of electricity in order to apply an electrical current between the electrodes. The anodization, to a certain extent, causes the silicon carbide crystal to electrochemically decompose in the region of the porous layer of silicon carbide. Instead of uniformly decomposing the silicon crystal, the electrochemical decomposition can locally remove silicon atoms from the crystal lattice of the silicon carbide, thus forming small holes or pores in the silicon carbide crystal. At the end of the treatment, the porosified portion is rinsed in order to remove the residues of the electrolyte.

In a porosification step, it is possible to conserve the non-porous structure of a portion of a substrate. In this case, the portion concerned is kept outside the electrolyte bath.

In some cases, the porosity thus formed is uniform over the entirety of the support substrate, except for the surface layer. In other embodiments, a porosity gradient that decreases from the rear face to the front face is produced, such that the porosity is lower by the surface layer and greater by the rear face. The porosity may also be increased gradually, by setting the porosification parameters first of all for a substrate of a certain thickness, and by continuing this porosification in portions of decreasing thickness extending from the rear face of the substrate. For each successive portion, the porosification parameters can be modified so as to create a greater porosity than in the preceding step.

It is possible to modify the porosity and create a gradient by varying the different parameters of the substrate such as the doping, and of the porosification process such as the applied current and voltage, the temperature, the composition of the electrolyte and, in certain cases, the intensity and wavelength of an applied light.

As an alternative, a porous portion may be formed by sintering silicon carbide before assembling the substrate. Sintering is a heat treatment of a structure made of silicon carbide at a temperature ranging between 1600° C. and 2400° C. in an atmosphere that may be, for example, argon, nitrogen or an inert gas. Such a heat treatment may modify the distribution of the carbon and the silicon that are present in the substrate, thus forming inclusions made of carbon in the silicon carbide.

In some embodiments, the porous zone may be formed directly in a substrate of monocrystalline silicon carbide comprising the surface layer, by porosifying the substrate over part of its thickness. In this case, the porosification is carried out from the rear face.

In other embodiments, the formation of the substrate may comprise assembling the support substrate and the surface layer. The porous zone of the support substate may be formed before or after the assembly.

In some embodiments, the formation of the support substrate may comprise one or more step(s) of assembling two or more porous portions, and/or a porous portion with a non-porous portion.

The layers or portions of substrates may be assembled by bonding, for example, from a donor substrate in which a weakened zone is created in order to delimit the layer to be assembled. In this case, use is typically made of a process of the Smart Cut™ type. A weakened zone for delimiting the layer to be assembled on the support substrate is formed in the donor substrate made of monocrystalline silicon carbide. The weakened zone is typically created by irradiation with ions, for example, hydrogen and/or helium ions. The donor substrate is then bonded to the front face of the support substrate, the layer delimited by the weakened zone being arranged in direct contact with the front face of the support substrate. The donor substrate is then detached along the weakened zone, in order to transfer the layer of monocrystalline silicon carbide to the support substrate, for example, by using a heat treatment.

Another technique for weakening a donor substrate is to create a weakened zone having a higher porosity than that of the material in the vicinity of this zone. In such a case, after bonding to the support substrate, the donor substrate can be detached by applying a mechanical stress. Such a mechanical stress is, for example, the insertion of a blade or another beveled tool, or the application of a jet of air or a jet of water. This technique can be used while transferring a porous layer or for a thinning operation as described below.

Another embodiment of the assembly is deposition on a provided portion of the substrate, for example, chemical vapor deposition (CVD) or physical vapor deposition (PVD). For example, it is possible to deposit a layer of polycrystalline silicon carbide by CVD or PVD on the surface layer of monocrystalline silicon carbide or on another layer of (porous or non-porous) polycrystalline silicon carbide, and porosify all or some of the deposited layer.

The step of assembling the support substrate and the surface layer of monocrystalline silicon carbide can be carried out on a base substrate intended to form a support substrate, on a finished support substrate, or at the end of one or more steps of forming the support substrate.

In the case of bonding two porous portions or a porous portion and a non-porous portion, the porosity of the bonding interfaces is with preference less than 40%, preferably less than 15% and more preferably less than 5% in order to ensure good adhesion between the two portions.

It is possible to carry out one or more optional thinning steps in order to set the thickness of the support substrate or a portion of the support substrate, and the porosity on its rear face. In order to carry out this thinning step, it is possible to create, from the rear side of the porous zone to be formed, a weakened zone having a porosity greater than 10%, advantageously greater than 15%, particularly advantageously greater than 30% relative to the porosity of the porous zone to be formed, at a determined depth corresponding to the thickness of the porous portion to be formed. Then, or after a step of assembly with one or more layers on the front face of the substrate, the substrate can be cut along the weakened zone created. The cut can be made by applying a mechanical stress, for example, by inserting a blade or by applying a jet of air or a jet of water. The stress must be adapted to spread a fracture wave along the weakened zone, which has a mechanical strength less than that of the zones surrounding the weakened zone. Advantageously, such a weakened zone is surrounded by a portion made of polycrystalline silicon carbide having a porosity lower than the weakened zone, for example, 1% or 5% less porosity, advantageously 10% less porosity.

In some embodiments, the substate is thinned by breaking a porous portion that leaves the porous zone, which will be fixed to the braze of the electronic component, on the surface. Such thinning avoids a polishing step that can be lengthy and expensive.

The thinning step may also be carried out by chemical etching or a mechanical abrasion technique.

With preference, a porous portion having a thickness greater than 100 nm, advantageously greater than 1 μm, and particularly advantageously greater than 3 μm is conserved. The thickness of the layer has an influence on the deformations caused by the variations in temperature. The mechanical stresses applied to the braze of the electronic chip thus decrease further as the thickness of the porous portion increases.

It is also possible to apply one or more thinning steps at the end of the creation of a porous portion, in order to set the thickness of the porous portion before assembly with another, porous or non-porous portion.

It is possible to carry out an optional step of passivation, or another treatment of the rear face, for example, by deposition of a dielectric layer, such as silicon oxide, which forms a barrier layer in order to avoid direct contact between the silicon carbide and the ambient air and, consequently, avoid the creation of a depletion zone, which involves a drop in the electrical conductivity of the rear face.

### EXEMPLARY EMBODIMENTS

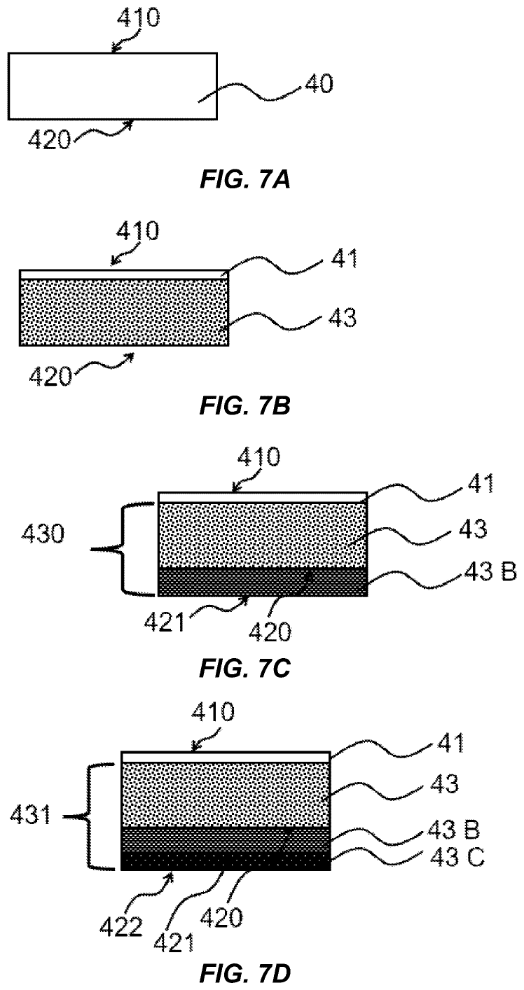

FIGS. 7A to 7D illustrate a process for manufacturing a substrate according to the present disclosure, in which the surface layer and the support substrate are produced from a single starting substrate 40 made of monocrystalline silicon carbide.

With reference to FIG. 7A, a front face 410, preferably a silicon face, is chosen. A treatment, for example, polishing, can be applied to the front face 410. The portion extending from this front face 410 is intended to form the surface layer 41.

Then, with reference to FIG. 7B, a porosity is formed from the rear face 420 of the portion intended to form the support substrate 43, such that no porosity is formed in the portion intended to form the surface layer 41.

It is then optionally possible to assemble one or more additional layers 43B, 43C on the rear face of the support substrate 43. The assembly of a first layer 43B is illustrated in FIG. 7C. The first layer 43B has a higher porosity than the portion 43 extending from the rear face 420 of the porosified single substrate. Such a layer is, for example, a layer made of sintered silicon carbide or a layer made of porosified silicon carbide, or a combination of two or more porous layers. A layer made of sintered silicon carbide can, for example, be obtained by reaction sintering at a temperature of approximately 2000° C. This forms a new rear face 421 of the support substrate 430 to be formed.

The optional assembly of a second layer 43C is illustrated in FIG. 7D. This assembly forms a new rear face 422 of the substrate to be formed. The second layer 43C has a higher porosity than the rear face of the first layer 43B. This forms a new support substrate 431, the porosity of which increases successively from the front face 410 to the rear face 422 of the support substrate 431 formed.

It is also possible to assemble one or more layers 43B, 43C on the rear face 420 of the substrate and/or carry out an additional porosification after the assembly (not illustrated). For example, it is possible firstly to bond a layer made of sintered silicon carbide to the rear face of the starting substrate, then deposit a layer of polycrystalline silicon carbide on the rear face of the layer made of sintered silicon carbide, and carry out a step of porosifying the layer made of polycrystalline silicon deposited on the layer made of sintered silicon carbide.

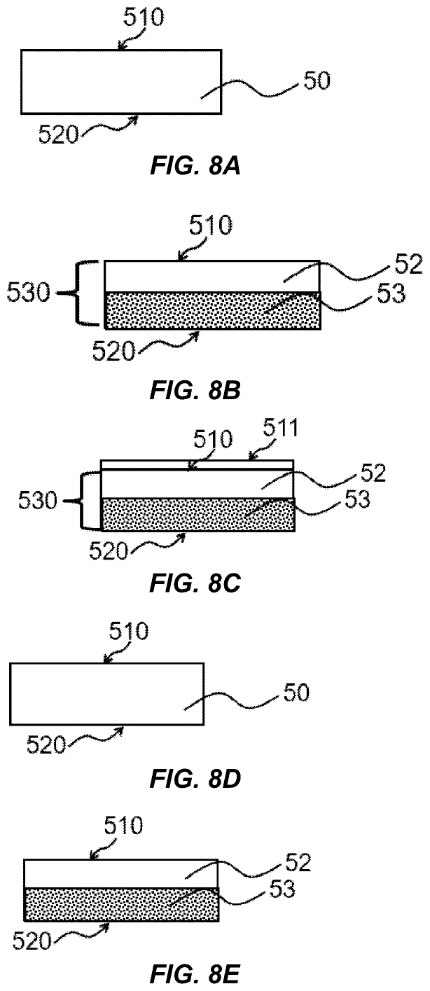

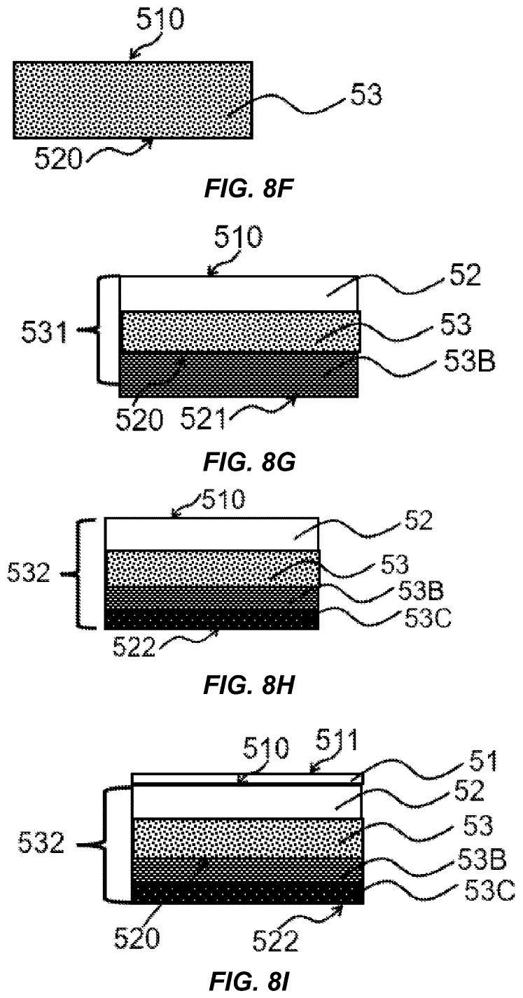

A preferred embodiment is illustrated in FIGS. 8A to 8C. First of all, a support substrate 530 is formed, and then it is assembled with a surface layer 51 made of monocrystalline silicon.

With reference to FIG. 8A, a support substrate is formed from a substrate 50 made of polycrystalline silicon carbide. With reference to FIG. 8B, a portion 53 intended to form the porous portion extending from the rear face 520 of the substrate to be formed is porosified. With reference to FIG. 8C, the support substrate on its front face 510 is assembled with a surface layer 51 of monocrystalline silicon carbide, typically using a process of the Smart Cut™ type as described above.

To illustrate the variants of such an embodiment, a more complex process is illustrated in FIGS. 8D to 8I. In this embodiment, first of all a support substrate is formed and then it is assembled with a surface layer 51 made of monocrystalline silicon carbide.

To form the support substrate, it is possible, with reference to FIG. 8D, to take a substrate 50 of polycrystalline silicon carbide as a basis. It is then possible to porosify the substrate as described above in order to form a porous zone 53 extending from the rear face 520 of the substrate 50. With reference to FIG. 8E, the porosification can be carried out such that only a portion 53 extending from the rear face 520 of the substrate has a porosity, by conserving a portion 52 extending from the front face 510 in its non-porous original state. Alternatively, it is possible to create a porosity gradient, such that the porosity increases successively or gradually from the front face 510 to the rear face 520 of the substrate 50. In other cases, with reference to FIG. 8F, the porosification is carried out uniformly over the entire thickness of the substrate as illustrated in FIG. 8B.

It is then possible, with reference to FIG. 8G, to carry out an optional step of bonding a layer 53B having a greater porosity to the rear face 520 of the substrate and thus create a new support substrate 531 having a new rear face 521. The layer 53B has a higher porosity than the portion 53 extending from the rear face 520 of the porosified single substrate. Such a layer is, for example, a layer made of sintered silicon carbide or a layer made of porosified silicon carbide with a greater porosity than that of the previously porosified portion 53, or a combination of two or more porous layers. This forms a new rear face 521 of the support substrate 531 to be formed. With reference to FIG. 8H, it is optionally possible to carry out an additional porosification step in a portion 53C extending from the new rear face 521 of the substrate to be formed. For this additional porosification step, the parameters will be chosen such that the portion 53C has a higher porosity than the porous layer 53B in its initial state. As a result, the porosity of the support substrate 532 increases progressively from its front face 510 to its rear face 522.

It is optionally possible to carry out one or more bonding operations of other layers having greater porosities to the rear face of the substrate (not illustrated).

It is optionally possible to assemble one or more layers having a lower porosity on the front face of the substrate (not illustrated).

With reference to FIG. 8I, the support substrate on its front face 510 is assembled with a surface layer 51 of monocrystalline silicon carbide.

If no layer is assembled on the front face of the substrate 532, the surface layer 51 made of monocrystalline silicon carbide can be assembled with the support substrate 532 between any two steps of the procedure for forming the support substrate 532.

In some embodiments that are not illustrated, part of the support substrate and the surface layer made of monocrystalline silicon carbide are assembled while the support substrate is being formed, before all the steps of forming the support substrate are completed.

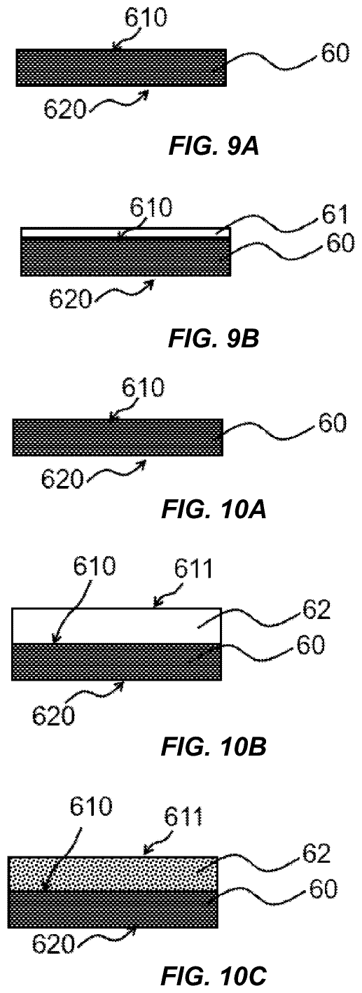

Other embodiments are illustrated in FIGS. 9A to 9B. With reference to FIG. 9A, the support substrate may be formed from a substrate 60 made of sintered silicon carbide. The sintered silicon carbide generally comprises carbon inclusions and is therefore a porous material, the pores of which are filled with these inclusions.

It is possible, with reference to FIG. 9B, to assemble the support substrate 60 of sintered silicon carbide with a surface layer 61 of monocrystalline silicon carbide on its front face 610. As a result, the substrate made of sintered silicon carbide forms a single porous zone 60 extending from its rear face 620.

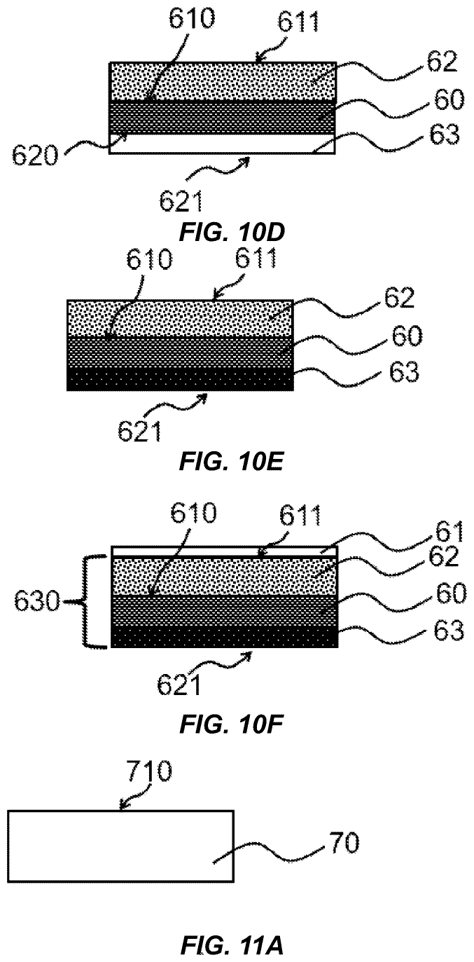

As an alternative, with reference to FIG. 10A, the same starting substrate 60 made of sintered silicon carbide is taken as a basis. With reference to FIG. 10B, a layer 62 of polycrystalline silicon carbide may be deposited on the front face 610 of the substrate 60 made of sintered silicon carbide. Such a deposition may, for example, be carried out by physical vapor deposition (PVD). Thus, the substrate 60 made of sintered silicon carbide is used as support and as crystallization seed for the polycrystalline silicon carbide. It is optionally possible to create a porosity in the layer 62 of silicon carbide thus deposited, as illustrated in FIG. 10C. In this case, the porosity created in the portion 62 deposited on the front face 610 is less than the porosity in the initial substrate 60 made of sintered silicon carbide. In some cases, the layer 62 is kept in its non-porous initial state.

Optionally, with reference to FIG. 10D, a second layer 63 of polycrystalline silicon carbide can be deposited on the rear face 620 of the substrate made of sintered silicon carbide, forming a new support substrate 630 having a new rear face 621. Then, with reference to FIG. 10E, a step of porosifying the layer 63 made of polycrystalline silicon carbide on the rear face 620 is carried out, such that the layer 63 on the rear face has a greater porosity than the substrate 60 made of sintered silicon carbide.

It is then possible to carry out optional steps (not illustrated) of bonding and/or assembling one or more layers having a greater porosity to or on the rear face of the substrate, or/or one or more layers having a lower porosity to or on the front face of the substrate.

With reference to FIG. 10F, the support substrate thus created is assembled with a surface layer 61 made of monocrystalline silicon carbide on the front face 611 of the support substrate.

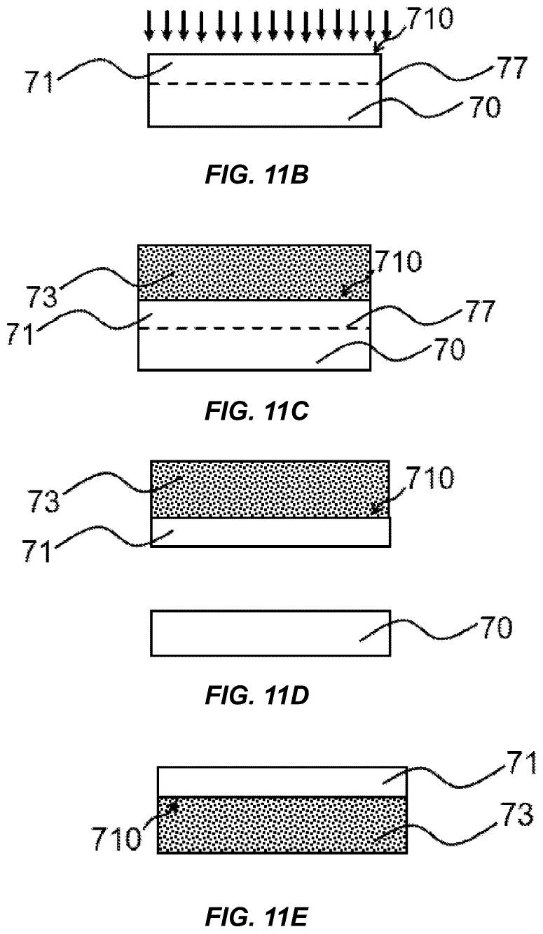

In another embodiment, with reference to FIG. 11A, a donor substrate 70 made of monocrystalline silicon carbide, one portion 71 on the front face 710 of which is intended to form the surface layer, is taken as a basis. With reference to FIG. 11B, a weakened zone 77 is formed to delimit the portion 71 intended to form the front face of the substrate to be formed. The weakened zone is preferably created by implanting hydrogen and/or helium atoms in the donor substrate.

With reference to FIG. 11C, a portion 73 made of polycrystalline silicon carbide is assembled on the front face 710. The porosity of the portion 73 may be formed before or after the portion 73 is assembled on the front face 71 of the donor substrate 70. For example, the portion 73 may be made of silicon carbide porosified or sintered before the bonding operation. Alternatively, the portion 73 made of polycrystalline silicon carbide may be deposited, for example, by CVD or PVD, on a donor substrate 70 made of monocrystalline silicon carbide, and a porosification step is carried out on the portion 73 after the deposition step.

The porosity of the portion 73 may be uniform, in the form of a gradient or multiple stages, or affect only a certain thickness of the substrate.

With reference to FIG. 11D, the donor substrate 70 is detached from the portion 71, for example, by way of a heat treatment. With reference to FIG. 11E, the portion 73 forms the support substrate made of porous silicon carbide, and the portion 71 forms the surface layer made of monocrystalline silicon carbide of the finished substrate.

In some embodiments, a substrate made of monocrystalline silicon carbide intended to form the surface layer is taken as a basis. Then, the support substrate is formed on the substrate made of monocrystalline silicon carbide, such that the front face of the substrate is in contact with the substrate made of monocrystalline silicon carbide. The formation of the support substrate may comprise one of more steps of depositing, porosifying, sintering and assembling multiple portions forming the support substrate. It is then possible to thin the substrate made of monocrystalline silicon carbide as described above.

It is then possible to form chips from such a substrate for radiofrequency and/or power electronics applications. When the device is designed for a radiofrequency application, the electronic chips may be formed in a layer of silicon carbide or of a nitride from the group III-N, for example, a stack of layers GaN/AlGaN/AlGanInN delimiting a two-dimensional electron gas. Such a layer or such a stack is borne by the surface layer made of monocrystalline silicon carbide.

### REFERENCES

Y. Shishkin et al.: Photoelectrochemical etching of n-type 4H silicon carbide, Journal of Applied Physics 96, 2311, 2004.
Gautier et al.: Electrochemical formation of porous silicon carbide for micro-device applications, Materials science forum, ISSN: 1662-9752, vol. 924, pages 943-946, 2018.
L.L. Snead et al., Journal of Nuclear Materials 371 (2007) 329-377.

1. A substrate for a radiofrequency or power electronic device, comprising:
a support substrate of polycrystalline silicon carbide having a front face and a rear face, the support substrate being self-supporting, the support substrate having at least one porous portion extending from the rear face, the porous portion having a porosity greater than 5%; and
a surface layer of monocrystalline silicon carbide extending on the front face of the support substrate.

2. The substrate of claim 1, wherein the support substrate has a thickness greater than 50 μm.

3. The substrate of claim 1, wherein the porous portion comprises a layer of porosified SiC.

4. The substrate of claim 1, wherein the support substrate further comprises a non-porous portion between the surface layer of monocrystalline SiC and the porous portion.

5. The substrate of claim 1, wherein the porous portion has a rear part having a first porosity and a front part having a second porosity less than the first porosity.

6. The substrate of claim 1, wherein the porous portion has a porosity gradient that decreases in a direction extending from the rear face toward the front face.

7. The substrate of claim 1, wherein the porous portion has pores filled with a material having a Young's modulus lower than a Young's modulus of the silicon carbide.

8. The substrate of claim 1, wherein the porous portion has pores, a mean distance between the pores being greater than 10 nm.

9. An electronic device, comprising:
a substrate according to claim 1; and
at least one radiofrequency or power electronic component formed in or on the surface layer of monocrystalline silicon carbide.

10. The electronic device of claim 9, further comprising a heat discharge device, the substrate being brazed to the heat discharge device via a filler such that the filler is in integral contact with at least part of the porous portion on the rear face of the support substrate.

11. A method of manufacturing a radiofrequency or power electronic device comprising:
a self-supporting support substrate of polycrystalline silicon carbide having a front face and a rear face; and
a surface layer of monocrystalline silicon carbide extending on the front face of the support substrate;
the method comprising forming, in the support substrate, at least one porous portion extending from the rear face, the porous portion having a porosity greater than 5%.

12. The method of claim 11, further comprising assembling the surface layer and the support substrate.

13. The method of claim 11, wherein the support substrate has a thickness greater than 50 μm.

14. The method of claim 11, further comprising forming the support substate, the forming of the support substrate comprising porosifying at least part of a base substrate of non-porous silicon carbide to form the porous portion.

15. The method of claim 14, wherein the porosification is carried out on all of the base substrate to form a completely porous support substrate.

16. The method of claim 14, further comprising forming the porous portion to exhibit a porosity gradient that decreases in a direction extending from the rear face to the front face.

17. The method of claim 14, wherein the porosification is carried out so as to form a bonding zone having a porosity of less than 40% on the front face of the support substrate.

18. The method of claim 11, further comprising filling at least some of the pores of the porous portion with a material having a Young's modulus lower than a Young's modulus of the silicon carbide.

19. The method of claim 11, further comprising thinning the support substrate via the rear face, such that a thickness of the porous portion remains greater than or equal to 100nm.

20. The substrate of claim 2, wherein the support substrate has a thickness greater than 150 μm.
